(19) United States
(12) Patent Application Publication
(10) Pub. No.: US 2014/0185252 A1
(43) Pub. Date: Jul. 3, 2014

(54) IMAGE DISPLAY DEVICE

(71) Applicant: Kabushiki Kaisha Toshiba, Tokyo (JP)

(72) Inventor: Hiroki SAKURADA, Akishima-shi (JP)

(73) Assignee: Kabushiki Kaisha Toshiba, Tokyo (JP)

(21) Appl. No.: 14/012,643

(22) Filed: Aug. 28, 2013

Related U.S. Application Data
(63) Continuation of application No. PCT/JP2013/058624, filed on Mar. 25, 2013.

(30) Foreign Application Priority Data
Dec. 27, 2012 (JP) 2012-286150

(51) Int. Cl. H05K 7/02

(52) U.S. Cl. CPC H05K 7/02
USPC 361/752; 361/679.01

(57) ABSTRACT

According to one embodiment, an image display device of an embodiment includes a display panel, a first attaching portion extending on a back surface of the display panel in a longitudinal direction and provided with a first aperture, and a first cover attached to the first attaching portion and partially covering the back surface of the display panel. The first cover has a first main body extending in a direction intersecting the longitudinal direction outside the first attaching portion, a first extending portion extending from the main body in the longitudinal direction, and a first projection protruding from the first extending portion and fitting into the first aperture.

### CROSS REFERENCE TO RELATED APPLICATIONS

This application is a Continuation Application of PCT Application No. PCT/JP2013/058624, filed Mar. 25, 2013 and based upon and claiming the benefit of priority from Japanese Patent Application No. 2012-286150, filed Dec. 27, 2012, the entire contents of all of which are incorporated herein by reference.

### FIELD

Embodiments described herein relate generally to an image display device comprising a display screen.

### BACKGROUND

In the market of flat-panel televisions, flat-panel televisions comprising larger display screens become the mainstream than before. There is a need for typical electronic apparatuses to resist shock and damage. This need also applies to flat-panel televisions.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a perspective view showing an image display device, which is an example of an electronic apparatus of a first embodiment, from a front direction thereof.

FIG. 2 is a perspective view showing the image display device shown in FIG. 1 from a back direction thereof.

FIG. 3 is a plan view of a back cover of the image display device shown in FIG. 2.

FIG. 4 is a plan view of the back cover shown in FIG. 2 from which a second cover is removed.

FIG. 5 is an exploded perspective view of first, third and fourth covers of the back cover shown in FIG. 4, from the side of an inner surface thereof.

FIG. 6 is a perspective view of the image display device shown in FIG. 2 from which the back cover is removed, from the back direction.

FIG. 7 is an enlarged perspective view of an area surrounding a third aperture on a second side of a first frame of the image display device shown in FIG. 6.

FIG. 8 is an enlarged plan view of an area surrounding a third projection, which is corresponding to the third aperture on the second side, of the third cover shown in FIG. 4.

FIG. 9 is an enlarged plan view of an area surrounding the third aperture on the second side of the image display device shown in FIG. 2 and the third projection fitting into the third aperture.

FIG. 10 is a cross-section view of the third aperture and third projection of the image display device shown in FIG. 9, in a direction intersecting the longitudinal direction of the display panel.

FIG. 11 is an enlarged perspective view of an area surrounding the third aperture on a first side of the first frame of the image display device shown in FIG. 6.

FIG. 12 is an enlarged plan view of an area surrounding the third projection, which is corresponding to the third aperture on the first side, of the third cover shown in FIG. 4.

FIG. 13 is an enlarged plan view of an area surrounding the third aperture on the first side of the image display device shown in FIG. 2 and the third projection fitting into the third aperture.

FIG. 14 is an enlarged perspective view of an area surrounding the first aperture in the first frame of the image display device shown in FIG. 6.

FIG. 15 is an enlarged plan view of an area surrounding the first projection of the first cover shown in FIG. 4.

FIG. 16 is an enlarged plan view of an area surrounding the first aperture on the first side of the image display device shown in FIG. 2 and the first projection fitting into the first aperture.

FIG. 17 is an exploded perspective view of an area surrounding the second frame and second projection of the image display device shown in FIG. 2.

FIG. 18 is an enlarged perspective view of an area surrounding overlaid and overlapping portions and a step of the image display device shown in FIG. 2.

FIG. 19 is an enlarged perspective view of an area surrounding overlaid and overlapping portions and a step of the image display device shown in FIG. 18.

FIG. 20 is an exploded perspective view of an area surrounding the first and second covers of the image display device shown in FIG. 2.

FIG. 21 is a cross section view of the first and second covers taken along a line F21-F21 of FIG. 20.

FIG. 22 is an enlarged plan view of first and third through-holes in the back cover shown in FIG. 4.

FIG. 23 is a perspective view of a back cover of an image display device that is an example of an electronic apparatus of a second embodiment.

FIG. 24 is an enlarged perspective view of an area surrounding an overlaid portion, an overlapping portion and a step portion of an image display device that is an example of the electronic apparatus of a third embodiment.

### DETAILED DESCRIPTION

An embodiment of the invention will provide a highly reliable image display device.

In general, according to one embodiment, an image display device of an embodiment includes a display panel, a first attaching portion extending on a back surface of the display panel in a longitudinal direction of the display panel and provided with a first aperture, and a first cover attached to the first attaching portion and partially covering the back surface of the display panel. Further, the first cover has a first main body extending in a direction intersecting the longitudinal direction at a position outside the first attaching portion; a first extending portion extending from the first main body in the longitudinal direction, and a first projection protruding from the first extending portion and fitting into the first aperture.

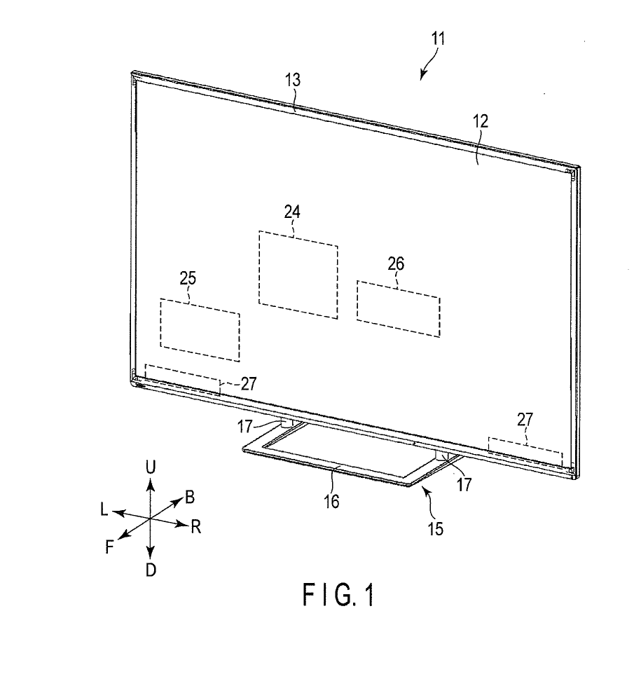

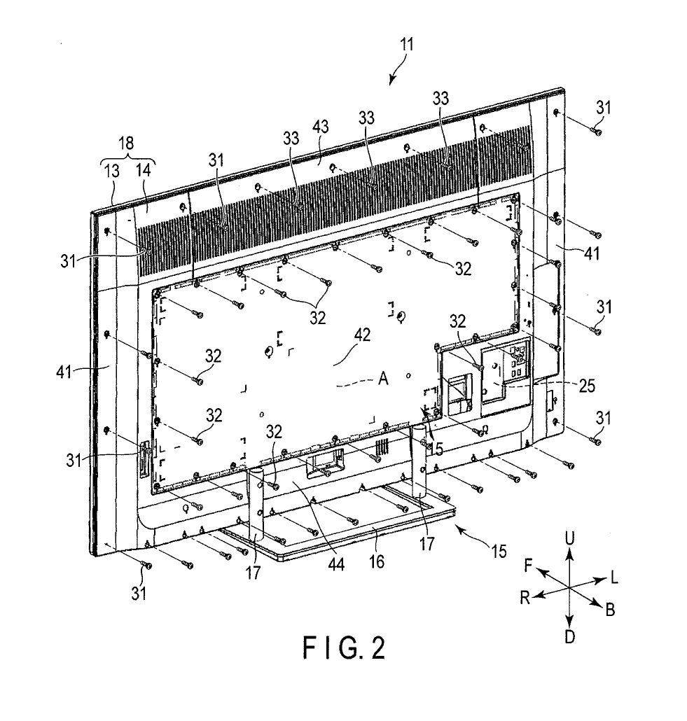

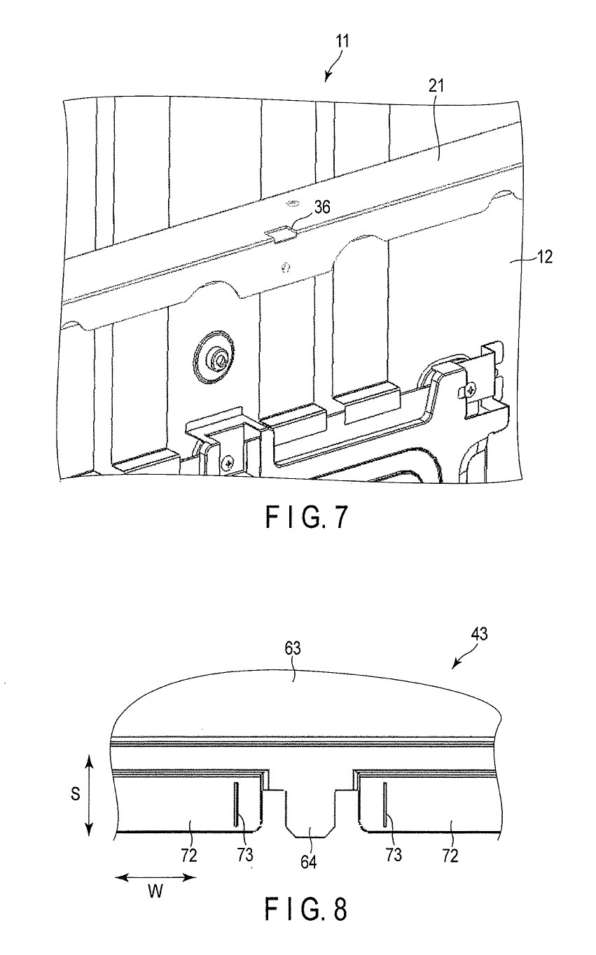

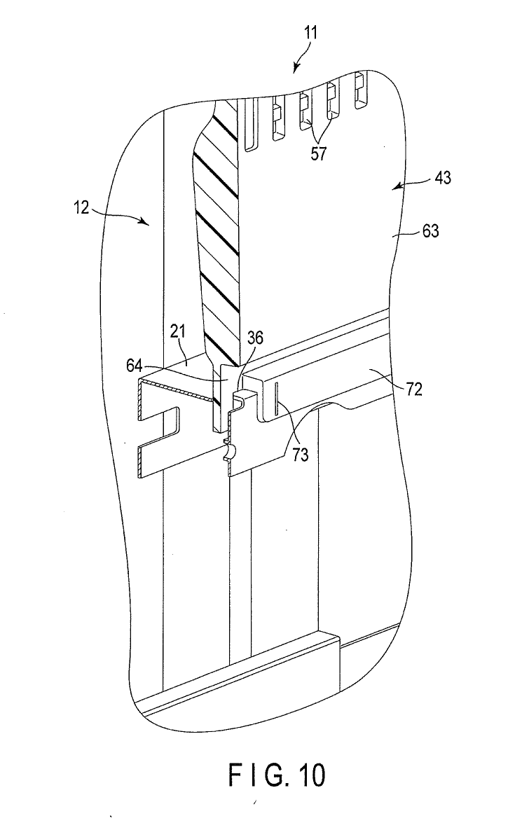

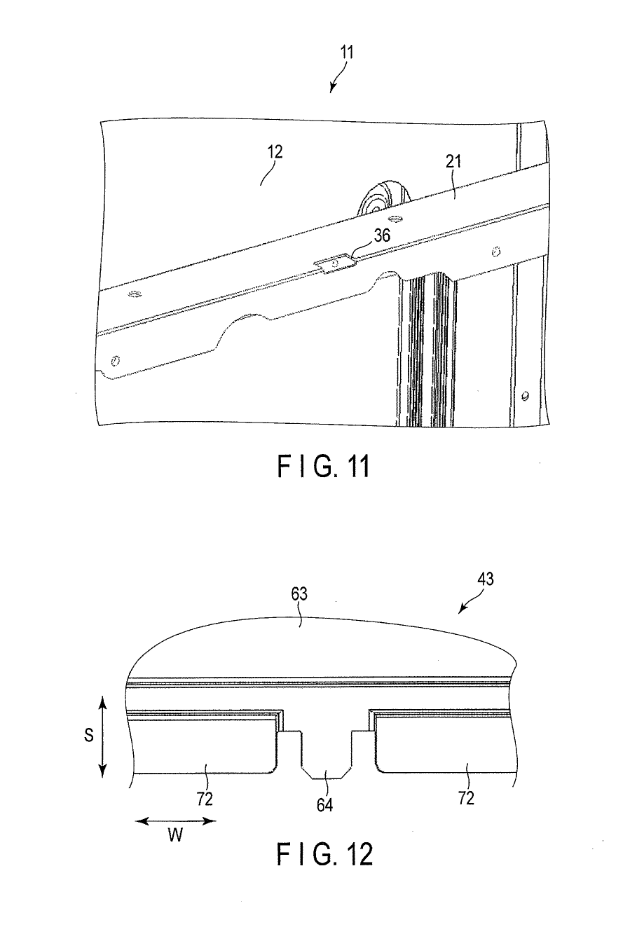

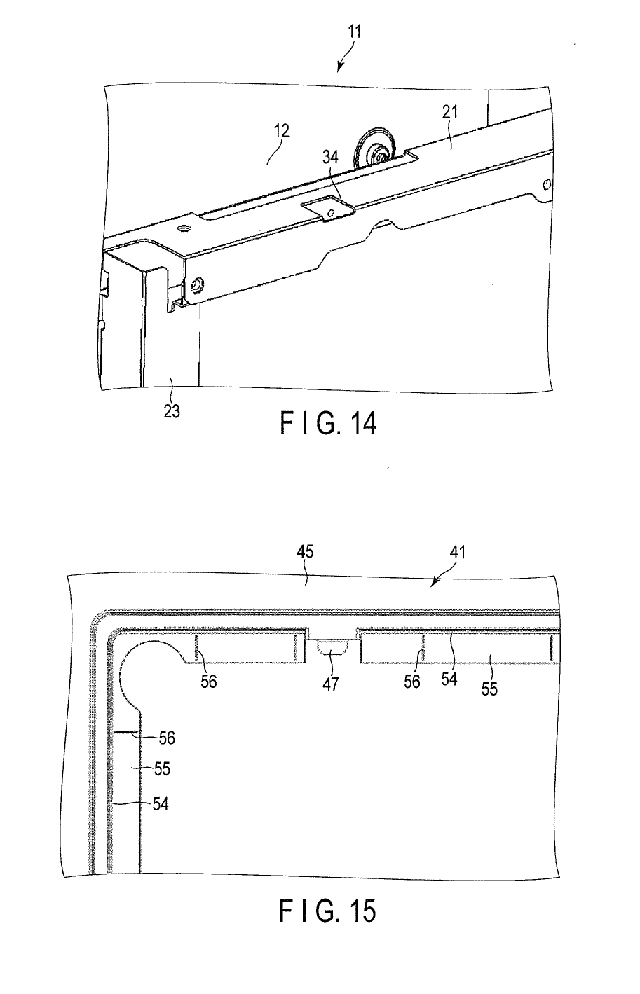

Hereinafter, a first embodiment of an image display device will be described with reference to FIGS. 1 to 22. As illustrated in FIGS. 1 and 2, the image display device, which is a television in this embodiment, of the embodiment is an example of an electronic apparatus, and is substantially rectangular in outer shape. The image display device comprises a large, for example, 84-inch display panel. In the following embodiments, a front side (or a user's side) is defined as a front direction F; a back side from the perspective of the user is defined as a back direction B; a left side from the perspective of the user is defined as a left direction L; a right side from the perspective of the user is defined as a right direction R; an upper side from the perspective of the user is defined as an upward direction U; and a lower side from the perspective of the user is defined as a downward direction D.

An image display device 11 is approximately 2 meters long in a longitudinal direction W of a display panel 12. As illustrated in FIGS. 1 and 2, the image display device 11 comprises: the flat display panel 12 configured to form a display screen; a mask 13 (or a front bezel) configured to cover the front of the display panel 12 by being placed in front of the display panel 12; a back cover 14 (or a cover) configured to cover the back of the display panel 12 by being placed in the back of the display panel 12; and a stand 15 (or a supporter) configured to support the display panel 12.

The display panel 12 is an integral display unit, and contains: liquid crystal cells; a light source for a backlight; a light guide plate configured to guide light from the light source in order to deliver the light to all the liquid crystal cells; various optical sheets configured to diffuse the light from the light guide plate; and a reflection sheet configured to reflect the light, which the light source has emitted toward the back of the light guide plate, toward the liquid crystal cells. It should be noted that the display panel 12 is not limited to a liquid crystal panel, and it may be some other display panel, such as a plasma display, an organic EL, a plastic display panel, or a sheet display panel.

The stand 15 comprises: a stand body 16 substantially formed in rectangular (or a frame-shaped) and flat and placed on an installed surface; and a pair of legs 17 extending from the stand body 16, having a bar-shape respectively, and configured to support the display panel 12.

The mask 13 has a frame shape (or an architrave shape), and is configured to expose the display panel 12 to the exterior through an aperture in the center thereof. The mask 13 and the back cover 14 constitute a housing 18 for the image display device 11.

As illustrated in FIGS. 1, 2 and 6, the image display device 11 comprises: a first frame 21 (as a first attaching portion) on the back surface of the display panel 12; a second frame 22 (as a second attaching portion) on the back surface of the display panel 12; a plurality of third frames 23 (as third attaching portions) on the back surface of the display panel 12; a system board 24 (as a circuit board) on the back surface of the display panel 12; a tuner board 25 on the back surface of the display panel 12; a power circuit board 26 on the back surface of the display panel 12; speakers 27; first fasteners 31 configured to attach first covers 41 of the back cover 14 to the display panel 12; second fasteners 32 configured to attach a second cover 42 of the back cover 14 to the display panel 12; and third fasteners 33 configured to attach a third cover 43 of the back cover 14 to the display panel 12.

Each of the first fasteners 31, the second fasteners 32, and the third fasteners 33 is configured of, for example, a screw. The system board 24 (as a circuit board) and the power circuit board 26 are provided in a region A between the first frame 21 and the second frame 22, or in the center of the back surface of the display panel 12.

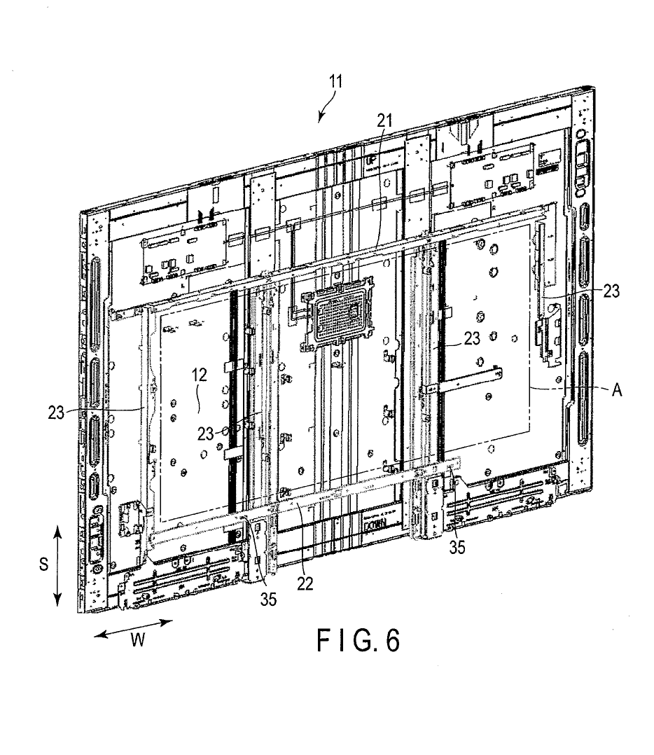

As shown in FIGS. 6, 7, 10, 11 and 14, the first frame 21 (as the first attaching portion) is formed by folding a flat metal plate (e.g. iron plate) such that its cross section has a substantially “C” or “U” shape. The first frame 21 extends in the longitudinal direction W (in other word, lateral direction, right/left direction, or horizontal direction) of the display panel 12, and is shorter than the display panel 12 in the longitudinal direction W. The first frame 21 is provided beside the center of the display panel 12. The first frame 21 comprises: a pair of first apertures 34 having a rectangular-shape and close to both the ends thereof; and a plurality of (e.g. three) third apertures 36 having a rectangular-shape and close to the center thereof.

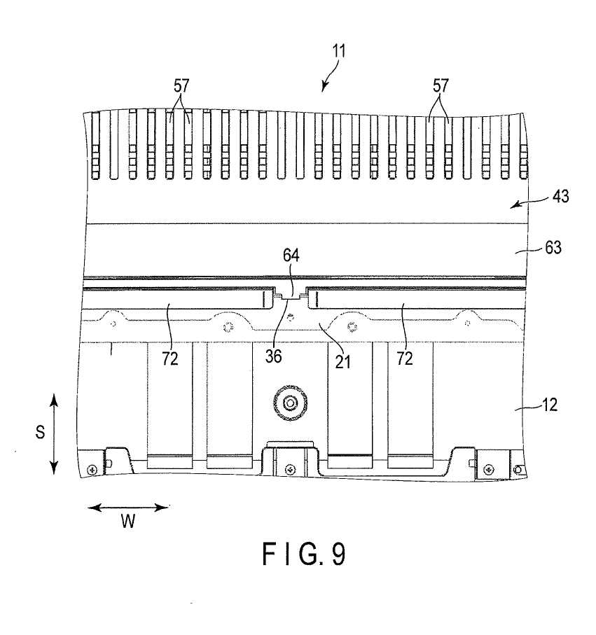

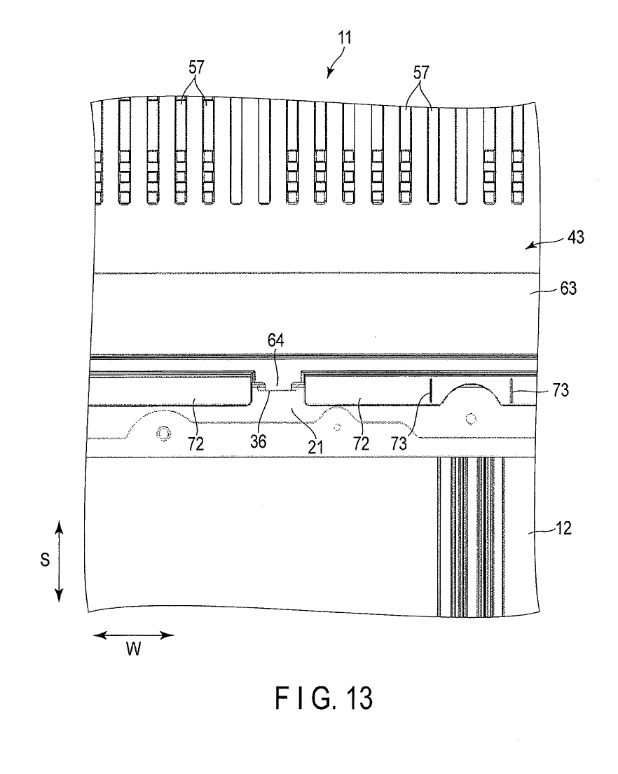

A one of the apertures 36 is larger than each third projection 64 of the third cover 43 in the longitudinal direction W, e.g. substantially 1.5 to 2 times as large as each third projection 64 in the longitudinal direction W, as shown in FIG. 13. Another one of the apertures 36 is substantially as large as each third projection 64 in the longitudinal direction W although the third aperture 36 contains a small gap, as shown in FIG. 9.

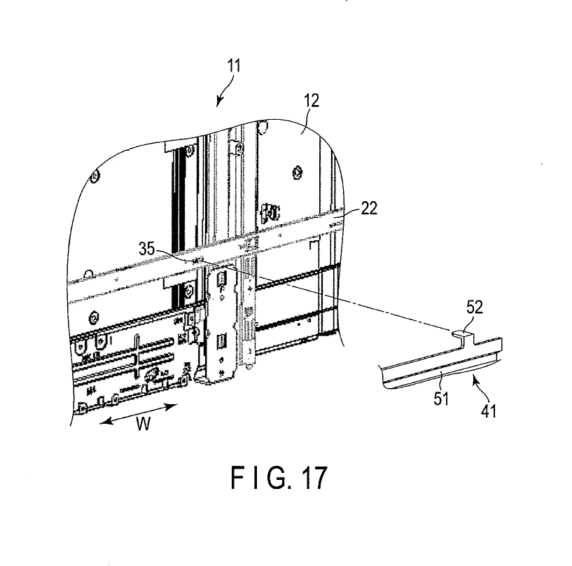

As shown in FIGS. 6 and 17, the second frame 22 (as the second attaching portion) is an elongated, flat metal plate (e.g. iron plate). The second frame 22 extends in the longitudinal direction W while being separated from the first frame 21. In addition, the second frame 22 is parallel to the first frame 21. The second frame 22 comprises a plurality of (e.g. two) rectangular second apertures 35. Each of the first frame 21 and the second frame 22 does not only configure an attaching portion for various components comprising the back cover 14, but also functions as a reinforcement configured to prevent the bending of the display panel 12.

As shown in FIG. 6, each of the third frames 23 extends in a direction S (in other word, a longwise direction, an upward/downward direction, or a vertical direction) intersecting the longitudinal direction W. In this embodiment, the four third frames 23 are provided. Each third frame 23 is formed by folding a flat metal plate (e.g. iron plate) in a desired shape. The third frames 23 are provided on the back surface of the display panel 12, and do not only configure attaching portions for various components but also function as reinforcements configured to prevent the bending of the display panel 12.

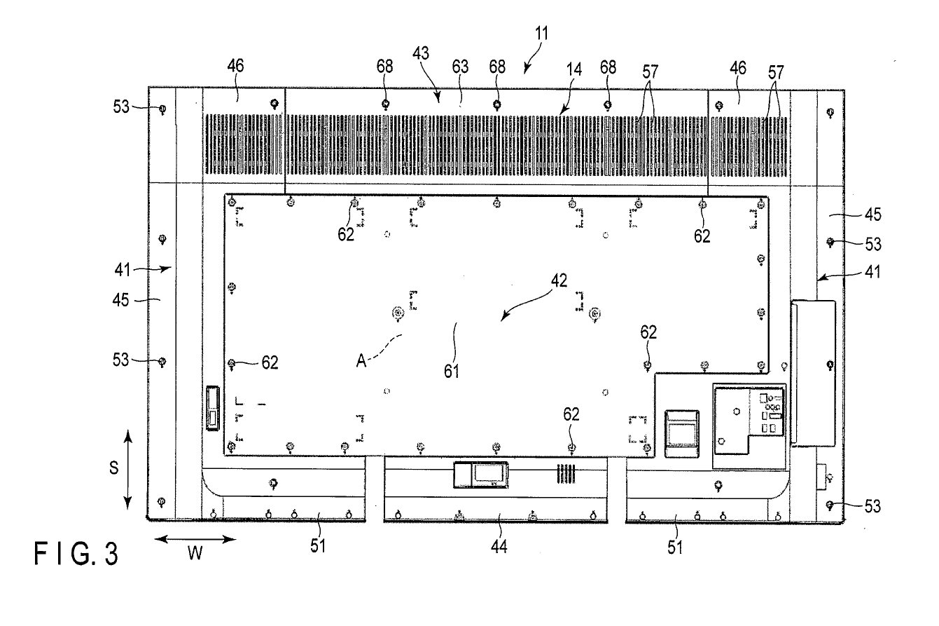

As shown in FIGS. 3 to 5, the back cover 14 comprises: the plurality of first covers 41 configured to cover portions of the back surface which correspond to the respective corners, where is the circumference of the display panel 12, on the back surface of the display panel 12; the second cover 42 configured to cover the center of the back surface of the display panel 12; the third cover 43 adjacent to first extending portions 46 between the first covers 41; and a fourth cover 44 between the pair of legs 17 of the stand 15 (in the circumference of the display panel 12). The fourth cover 44 is, for example, a rectangular plate made of synthetic resin.

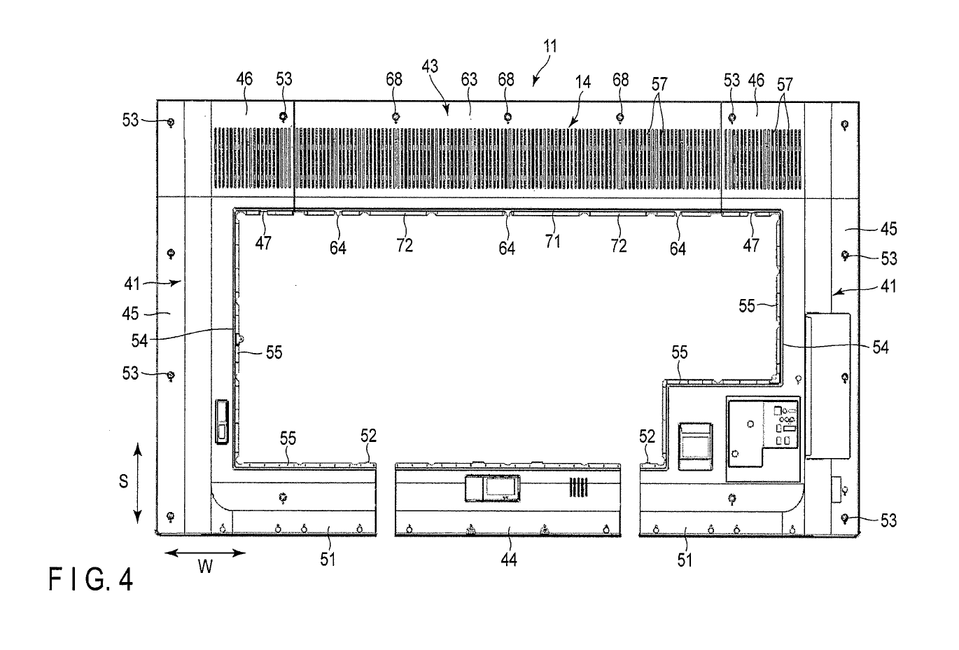

In this embodiment, the two first covers 41 are provided. Each of the first covers 41 is formed by integrally molding, for example, synthetic resin in a substantially “C” shape. It should be noted that the first cover 41 shown at the right hand in FIG. 4 and the first cover 41 shown at the left hand in FIG. 4 comprise substantially the same configuration, except a few parts in the shape. Each first cover 41 is attached to the first frame 21 and the second frame 22.

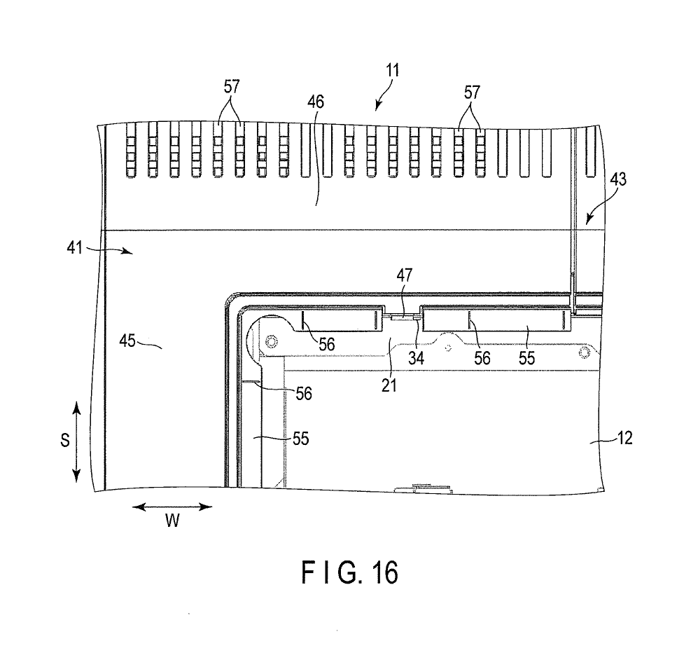

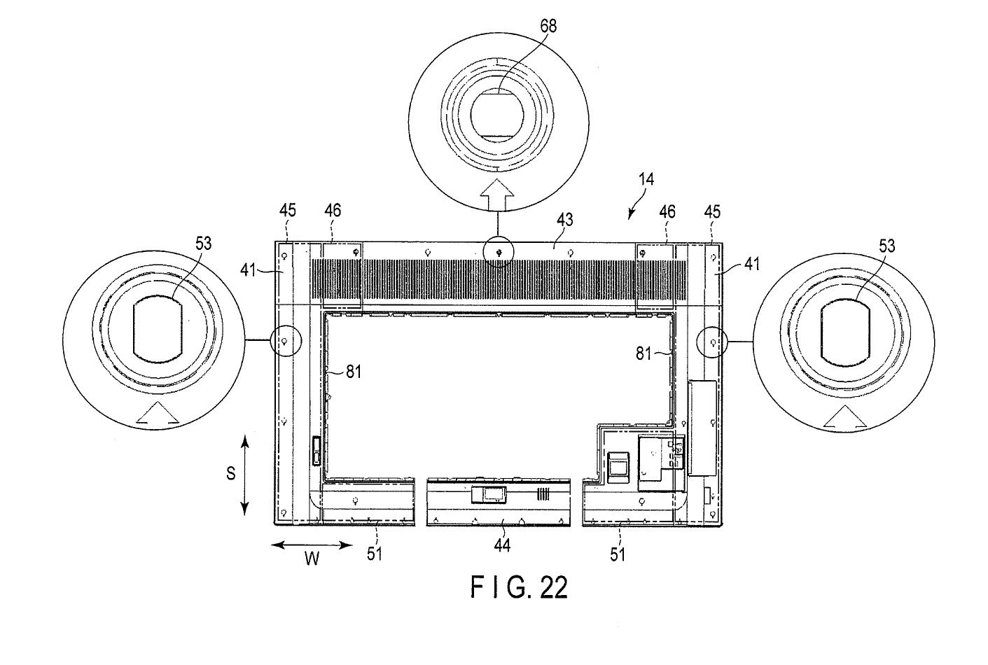

As shown in FIGS. 4, 5 and 22, each first cover 41 comprises: a first main body 45 extending in the direction S intersecting the longitudinal direction W; the first extending portion 46 extending from one end (which is upper end) of the first main body 45 in the longitudinal direction W; a first projection 47 protruding in a direction from the first extending portion 46 to the first frame 21 that is in the direction S intersecting the longitudinal direction W, as shown in FIG. 16; an overlapping portion 48 configured to overlap an overlaid portion of the third cover 43 in the first extending portion 46; a second extending portion 51 extending from other end (which is lower end) of the first main body 45 in the longitudinal direction W; and the second projection 52 protruding in a direction, which is forward direction, from the second extending portion 51 to the second frame 22 as shown in FIG. 17. It should be noted that as shown in FIG. 22, respective boundary between the first main body 45 and the first extending portion 46 and between the first main body 45 and the second extending portion 51 are each configured of a line drawn by extending an inner circumference 81 of the first cover 41 in the direction S intersecting the longitudinal direction W. In addition, each of the first extending portion 46 and the second extending portion 51 extend in the longitudinal direction W from a line drawn by extending the inner circumference 81 in the direction S intersecting the longitudinal direction W.

As shown in FIG. 16, each first main body 45 is provided outside the first frame 21. Each first projection 47 is configured to fit into the corresponding first aperture 34. As shown in FIG. 17, each second projection 52 is configured to fit into the corresponding second aperture 35. Each of the first extending portions 46 and second extending portions 51 is provided outside the region A.

As shown in FIGS. 3 and 4, each of the first covers 41 comprises: a plurality of first through-hole 53 configured to allow the first fasteners 31 to pass therethrough; a first groove 54 formed on the inner circumference of each first cover 41 and configured to be attached the second cover 42; a first supporter 55 provided inside the first groove 54 and configured to support the second cover 42; and a plurality of first chips 56 protruding from the first supporter 55 and configured to abut against the second cover 42, as shown in FIG. 16.

As shown in FIG. 22 and the like, the first through-holes 53 formed at the first main body 45 have an oval shape that is longer in the direction S intersecting the longitudinal direction W. Meanwhile, the first through-hole 53 formed at the first extending portion 46 has an oval shape that is longer in the longitudinal direction W (see FIG. 4). As shown in FIG. 4, the first through-hole 53 formed at each first extending portion 46 is arranged in close proximity to the third cover 43, and this first through-hole 53 and the first fastener 31 passing through it prevent the lifting of the third cover 43, that is the lifting prevention structure. Each first extending portion 46 is provided with a plurality of vents 57 for exhausting warm air inside the housing 18 to the exterior. An inner surface of each first extending portion 46 is provided with a plurality of reinforcing ribs 74.

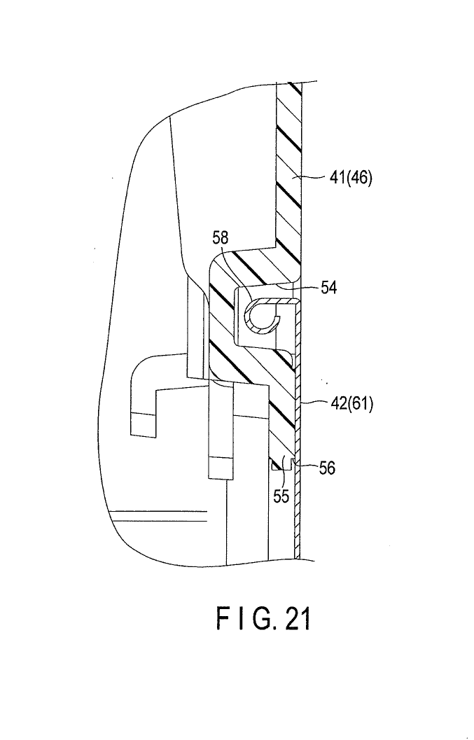

As shown in FIGS. 3 and 21, the second cover 42 is, for example, a substantially flat plate made of metal, such as iron. The outer circumference of the second cover 42 is provided with bent portions 58, each of which is bent such that its cross section becomes circular, in order to fit into the grooves in each first covers 41 and the third cover 43. The second cover 42 comprises: a second main body 61; and a plurality of second through-holes 62 formed in the second main body 61 and configured to allow the second fasteners 32 to pass therethrough.

As shown in FIG. 3, the second cover 42 is configured to cover the region A between the first frame 21 and the second frame 22. The second cover 42 is configured to electromagnetically shield the region A between the first frame 21 and the second frame 22, in order to prevent electromagnetic waves which the system board 24, the power circuit board 26 and the like emit in the region A from leaking to the exterior. Thus, the second cover 42 functions as an electromagnetic shield that covers the region A. Specifically, the metal case of the display panel 12, the second cover 42, the first frame 21, the second frame 22, and the third frames 23 constitute a shield case that prevents the leaking of the electromagnetic waves. The region A is surrounded by this shield.

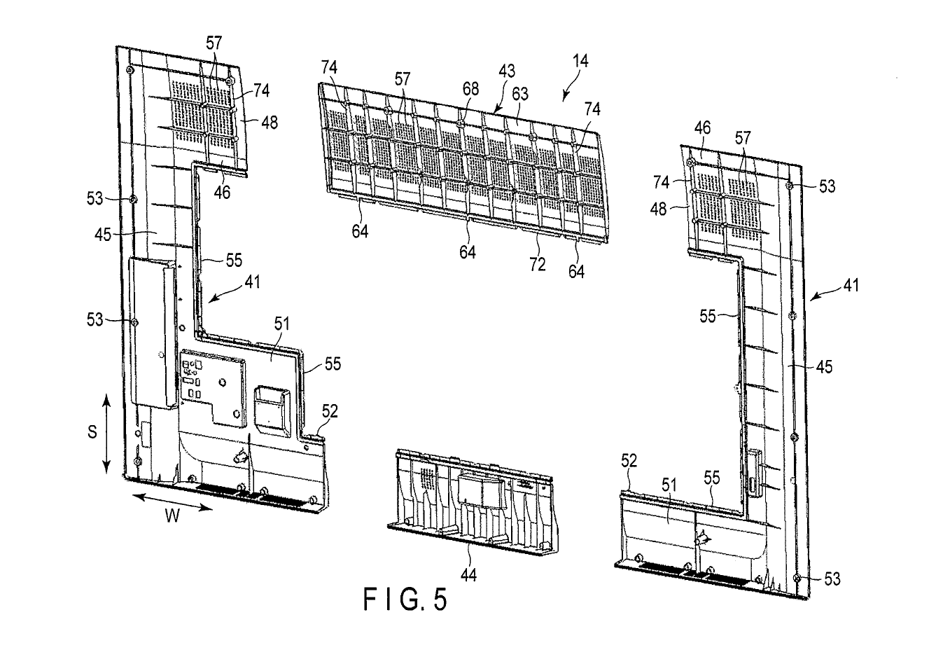

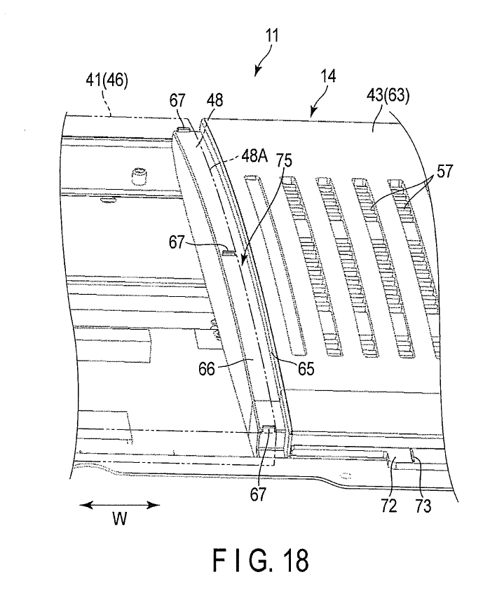

As shown in FIGS. 4 and 5, the third cover 43 is a substantially rectangular plate made of, for example, synthetic resin. The third cover 43 is attached to the first frame 21. The third cover 43 is disposed outside the region A. As shown in FIG. 18, the third cover 43 has a circular arc shape, for example, which is curved outward toward the back.

As shown in FIGS. 4, 5, 8, 10 and 12, the third cover 43 comprises: a third main body 63 extending in the longitudinal direction W; and the third projections 64 (as projections) protruding in a direction from the third main body 63 to the first frame 21, i.e., in the direction S intersecting the longitudinal direction W (see FIGS. 9 and 13). As shown in FIGS. 9 and 13, each of the third projections 64 is configured to fit into the corresponding third aperture 36. In addition, each of the third projections 64 is configured to fit into the corresponding third aperture 36. Any one of third projections 64 is configured to slide and move in the corresponding one of third aperture 36 in the longitudinal direction W, before or after the thermal expansion of the third cover 43 (see FIG. 13).

As shown in FIGS. 4, 18 and so on, the third cover 43 comprises: steps 65 at sites of the third main body 63 which are adjacent to the first covers 41, respectively; overlapped margins 66 protruding in a direction from the steps 65 to the first covers 41, respectively; a plurality of rails 67 on each overlapped margin 66 protruding toward each overlapping portion 48; a plurality of third through-holes 68 configured to allow the third fasteners 33 to pass therethrough; a third groove 71 on the inner circumference of the first covers 41 configured to receive the second cover 42; third supporters 72 inside the respective third groove 71 configured to support the second cover 42; and a plurality of third chips 73 protruding from the respective third supporters 72 and abutting against the second cover 42.

The third main body 63 is provided with a plurality of vents 57 for exhausting warm air inside the housing 18 to the exterior. The third cover 43 abuts against the overlapping portions 48 of the first covers 41 through the rails 67. As shown in FIG. 22, each third through-hole 68 is formed in an oval shape that is longer in the longitudinal direction W.

As shown in FIG. 5, the inner surface of the third cover 43 is provided with the plurality of reinforcing ribs 74 that are thinner than the third main body 63 of the third cover 43. It should be noted that because of a difference in curing rate between the molded resins, i.e., thin reinforcing ribs 74 are cured before the thick third main body 63 is cured second, the third cover 43 tend to be molded in a curved shape such that both the ends are lifted. Therefore, the above lifting prevention structure effectively functions.

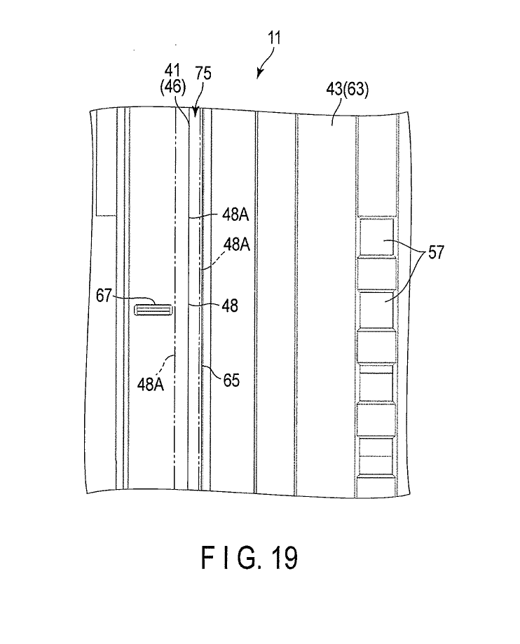

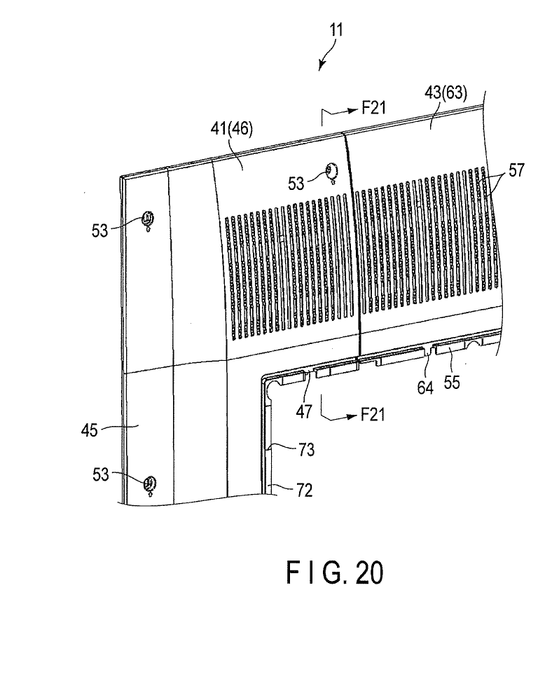

As shown in FIG. 18, a gap 75 is provided between the overlapping portion 48 of each first cover 41 and the corresponding step 65 of the third cover 43. In a normal state, an end surface 48A of each overlapping portion 48 is disposed at a location indicated by a solid line in FIG. 19, and the gap 75 between each overlapping portion 48 and the corresponding step 65 is set to 1.5 mm, for example. When the image display device 11 operates and the first covers 41 and the third cover 43 thermally expand in the longitudinal direction W, the end surface 48A of each overlapping portion 48 abuts against the corresponding step 65, as indicated by a dashed double-dotted line in FIG. 19. Meanwhile, when a temperature of a room in which the image display device 11 is disposed decreases, and the first covers 41 and the third cover 43 shrink in the longitudinal direction W, the gap 75 (e.g. 3 mm) that is larger than that in the normal state is formed between the end surface 48A of each overlapping portion 48 and the corresponding step 65, as indicated by a dashed double-dotted line in FIG. 19. Even when the first covers 41 and the third cover 43 shrink in this manner, the rails 67 and the interior of the image display device 11 are not exposed to the exterior. Consequently, the appearance is maintained properly.

A description will be given of an assembly process of the image display device 11 of this embodiment. The image display device 11 of this embodiment is assembled while the display panel 12 is in a stand-up position. Specifically, the display panel 12 is assembled with the stand 15, and stands by itself. The mask 13 is attached to the front surface of the display panel 12 with predetermined means. The first frame 21, the second frame 22, and the third frames 23 have been attached to the back surface of the display panel 12 in advance. First, the system board 24, the tuner board 25, and the power circuit board 26 are attached to the back surface of the display panel 12 with fastener means, such as screws. In particular, the system board 24 and the power circuit board 26 are fastened in the region A between the first frame 21 and the second frame 22. It should be noted that the tuner board 25 has been provided with a shield structure for preventing the leaking of electromagnetic waves, in advance.

Then, the third cover 43 is temporally attached to the first frame 21 by inserting the third projections 64 of the third cover 43 into the third apertures 36 of the first frame 21, for example (see FIGS. 9 and 13). Subsequently, the first extending portion 46 of each first cover 41 is temporally attached to the first frame 21 by inserting the first projection 47 of each first cover 41 into the corresponding first aperture 34 of the first frame 21 (see FIG. 16). In this state, each first cover 41 may rotate around the corresponding first projection 47. Accordingly, the second projection 52 of each first cover 41 is inserted into the corresponding second aperture 35 of the second frame 22 (see FIG. 17). Since each first cover 41 is maintained at upper and lower portions (which are both the ends), each first cover 41 is temporally attached to the first frame 21 and the second frame 22 without rotating. As shown in FIG. 2, then, each first cover 41 is attached to the display panel 12 by the first fasteners 31, and the third cover 43 is attached to the display panel 12 by the second fasteners 32. Further, the fourth cover 44 is attached to the display panel 12 with attaching means, such as screws. Finally, the second cover 42 is temporally attached to the first covers 41, the third cover 43 and the fourth cover 44 by inserting the bent portions 58 of the second cover 42 into the first grooves 54 of the first covers 41, the third groove 71 of the third cover 43, and the groove of the fourth cover 44. The second cover 42 in this state is attached to the display panel 12 with the second fasteners 32. As a result, the image display device 11 is completed. It should be noted that in this state, the second cover 42 prevents the leaking of the electromagnetic waves outside the region A.

According to the first embodiment, the image display device 11 comprises: the display panel 12; the first attaching portion extending in the longitudinal direction W of the display panel 12 on the back surface of the display panel 12 and provided with the first apertures 34; and the first covers 41 attached to the first attaching portion and configured to partially cover the back surface of the display panel 12. Each first cover 41 comprises: the first main body 45 extending in a direction intersecting the longitudinal direction W outside the first attaching portion; the first extending portion 46 extending from the first main body 45 in the longitudinal direction W; and the first projection 47 protruding from the first extending portion 46 and configured to fit into a corresponding one of the first apertures 34.

With this configuration, since each first main body 45 extends in the direction intersecting the longitudinal direction W outside the first attaching portion, the first projections 47 and the first apertures 34 can be visually observed during the assembly operation. In addition, the first covers 41 can be temporally attached to the first attaching portion by using the first projections 47. It is thus possible to improve the workability.

The image display device 11 comprises the second attaching portion extending in the longitudinal direction W on the back surface of the display panel 12 while being separated from the first attaching portion, the second attaching portion being provided with the second apertures 35. Each first cover 41 comprises: the second extending portion 51 extending from the first main body 45 in the longitudinal direction W; and the second projection 52 protruding from the second extending portion 51 and configured to fit into a corresponding one of the second apertures 35.

With this configuration, when temporally attached to the first attaching portion by using the first projections 47, each first cover 41 can be prevented from rotating around the corresponding first projection 47. It is thus possible to stabilize the first covers 41 upon temporal attaching and to improve the workability of permanent attaching operation and so on.

The image display device 11 comprises: the circuit board in the region A between the first attaching portion and the second attaching portion on the back surface of the display panel 12; and the second cover 42 made of metal and configured to cover the region A. With this configuration, an electromagnetic shield can be constituted by the second cover 42. It is thus possible to prevent electromagnetic waves generated by the circuit board from leaking to the surroundings.

Each of the first covers 41 is made of resin, and each of the first extending portions 46 and the second extending portions 51 is provided outside the region A. This configuration permits the first covers 41, each made of resin, to be arranged in a so-called outer circumferential region of the back surface. As a result, precise shapes such as the vents 57, the reinforcing ribs 74 and the first projection 47, can be created by the resin, and the first covers 41, which are created in the precise shape, can be arranged in the outer circumferential region of the display panel 12. It is thus possible to improve the functionality of the first covers 41.

The image display device 11 comprises the third cover 43, made of resin, adjacent to the first extending portions. 46 and extending in the longitudinal direction W outside the region A. In addition, the gap 75 is provided between each first extending portion 46 and the third cover 43. With this configuration, when the first covers 41 and the third cover 43 thermally expand, they can be prevented from abutting against each other and being deformed in arched shape.

In the image display device 11, one of each first extending portion 46 and the third cover 43 comprises the step 65 and the overlapped margin 66 protruding from the step 65; the other one comprises the overlapping portion 48 configured to overlap the overlapped margin 66; and the gap 75 is provided between the step 65 and the overlapping portion 48. With this configuration, the internal structure of the image display device 11 can be prevented from being viewed through each gap 75, because each gap 75 is provided at a location where the overlapped margin 66 is covered. It is thus possible to improve the appearance.

Each overlapped margin 66 is provided with the plurality of rails 67 that protrude in order to abut against the overlapping portion 48. With this configuration, a frictional force generated between the overlapped margin 66 and the overlapping portion 48 can be decreased upon thermal expansion. Therefore, the first covers 41 and the third cover 43 thermally expand readily. Since the overlapped margin 66 and the overlapping portions 48 make point contact with each other through the rails 67, it is possible to reduce the molding precision for each overlapping portion 48, in particularly its inner surface, and to lower the cost.

Each first cover 41 comprises a plurality of chips configured to abut against the second cover 42. The third cover 43 comprises a plurality of chips configured to abut against the second cover 42. With these configurations, the second cover 42 makes point contact with each first cover 41 and the third cover 43. It is thus possible to prevent the continuous vibration of the second cover 42 which is caused due to vibration generated at the speakers 27 and the like transfer from the first cover 41 and the third cover 43 to the second cover 42 through.

The image display device 11 comprises the first fasteners 31 configured to attach the first covers 41 to the display panel 12. In addition, each first main body 45 is provided with the first through-holes 53, each of which is longer in the direction intersecting the longitudinal direction W, and the first through-holes 53 are configured to allow the first fasteners 31 to pass therethrough. Likewise, the image display device 11 comprises the third fasteners 33 configured to attach the third cover 43 to the display panel 12. In addition, the third cover 43 is provided with the third through-holes 68, each of which is longer in the longitudinal direction W, and the third through-holes 68 are configured to allow the third fasteners 33 to pass therethrough.

With these configurations, the first cover 41 can be prevented from cracking when thermal expansion has been occurred in the first cover 41 during the operation of the image display device 11.

The image display device 11 comprises the third apertures 36 in the first attaching portion. The third cover 43 comprises: the third main body 63; and the third projections 64 protruding from the third main body 63 and configured to fit into the third apertures 36. A length of third aperture 36 in the longitudinal direction W is larger than that of third projection 64 in the longitudinal direction W. The third projections 64 are configured to move in the third apertures 36, before or after the thermal expansion of the third cover 43, respectively.

With this configuration, the movement of the third projection 64 can be permitted upon thermal expansion of the third cover 43. It is thus possible to prevent the third cover 43 from being lifted or deformed.

The image display device 11 comprises: the display panel 12 provided with the attaching portion; the first covers 41 made of resin, attached to the attaching portion, and configured to cover the outer circumference of the back surface of the display panel 12; the second cover 42 made of metal, attached to the attaching portion, and configured to cover the center of the back surface of the display panel 12; and the circuit board in the center of the back surface of the display panel 12.

With this configuration, an electromagnetic shield can be configured by the second cover 42 made of metal, and electromagnetic waves generated by the circuit board can be prevented from leaking out of the shield. In addition, first cover 41 made of resin can be disposed on the outer circumference, and precise shapes, such as the vents 57, the reinforcing ribs 74, and other various projections, can be formed using resin. It is thus possible to improve the functionality of each first cover 41.

The image display device 11 comprises: the display panel 12 provided with the attaching portion; the first covers 41 made of resin, attached to the attaching portion and configured to cover the back surface of the display panel 12; and the third cover 43 made of resin, attached to the attaching portion and configured to cover the back surface of the display panel 12. One of each first cover 41 and the third cover 43 comprises the step 65 and the overlapped margin 66 extending from the step 65; the other one comprises the overlapping portion 48 configured to overlap the overlapped margin 66. In addition, the gap 75 is provided between the step 65 and the overlapping portion 48.

With this configuration, the first covers 41 and the third cover 43 can be prevented from abutting against each other and being deformed in arched shape when the first covers 41 and the third cover 43 thermally expand. Moreover, the internal structure of the image display device 11 can be prevented from being viewed through each gap 75, because each gap 75 is provided at a location where the corresponding overlapped margin 66 is covered. It is thus possible to improve the appearance.

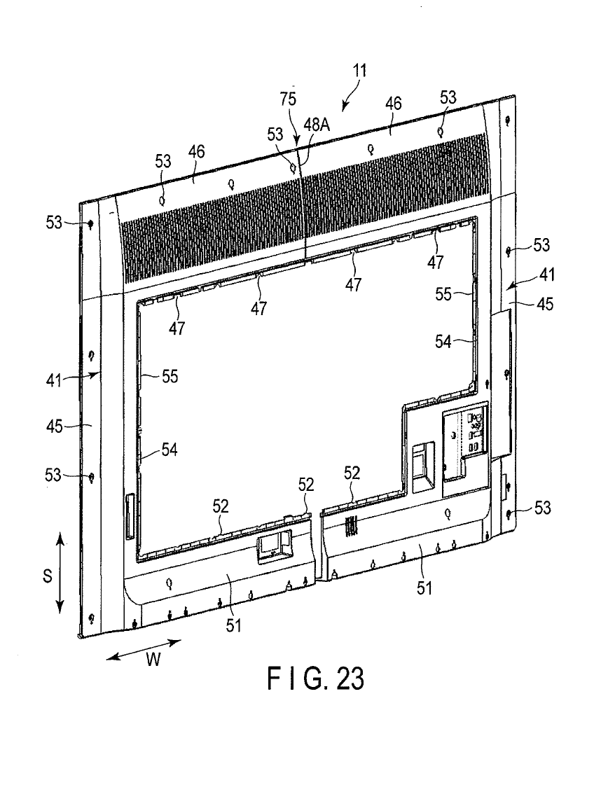

Next, a description will be given of a second embodiment of the electronic apparatus, with reference to FIG. 23. An image display device 11, which is an example of the electronic apparatus of the second embodiment, differs from that of the first embodiment, in that the third cover 43 and the fourth cover 44 are not comprised and in that the stand 15 is configured of the single leg 17, but other parts thereof are the same as those of the first embodiment. For this reason, the different parts from the first embodiment will be mainly described, and a description or illustration of the same parts will be omitted.

The image display device 11 of the second embodiment is a more compact model than the first embodiment, and contains a substantially 65-inch display panel 12, for example.

In this embodiment, two first covers 41 are provided. Each of the first covers 41 is integrally molded in a substantially “C” shape with synthetic resin.

Each of the first covers 41 comprises: a first main body 45 extending in a direction S intersecting the longitudinal direction; a first extending portion 46 extending from an one end (e.g. upper end) of the first main body 45 in the longitudinal direction W; first projections 47 protruding in a direction from the first extending portion 46 to the first frame 21 (i.e., in the direction S intersecting the longitudinal direction W); a second extending portion 51 extending from the other end (e.g. lower end) of the first main body 45 in the longitudinal direction W; and a second projection 52 protruding in a direction from the second extending portion 51 to the second frame 22 (i.e., in the front direction).

Each of the first covers 41 comprises: a plurality of first through-holes 53 configured to allow the first fasteners 31 to pass therethrough; a first groove 54 in the inner circumference of each first cover 41 configured to receive the second cover 42; a first supporter 55 inside the first groove 54 supporting a second cover 42; and a plurality of first slips 56 protruding from the first supporter 55 and configured to abut against the second cover 42.

The first extending portion 46 of one of the first covers 41 is provided with an overlapping portion 48 that is configured to overlap an overlapped margin 66 of the other of the first covers 41. The first extending portion 46 of the other of the first covers 41 is provided with: a step 65 adjacent to the one of the first covers 41; the overlapped margin 66 protruding in a direction from the step 65 to the one of the first covers 41; and a plurality of rails 67 protruding toward the overlapping portion 48 on the overlapped margin 66.

A gap 75 is provided between the overlapping portion 48 and the step 65, and conditions of the gap 75, comprising its dimension, are the same as those of the first embodiment.

According to the second embodiment, the first projections 47 and the first apertures 34 can be visually observed during the assembly operation even when the third cover 43 is not provided. In addition, each first cover 41 can be temporally attached to the first attaching portion adopting the first projections 47. Consequently, it is possible to improve the workability. Moreover, the two first covers 41 can be prevented from abutting against each other and being deformed in arched shape when the two first covers 41 thermally expand.

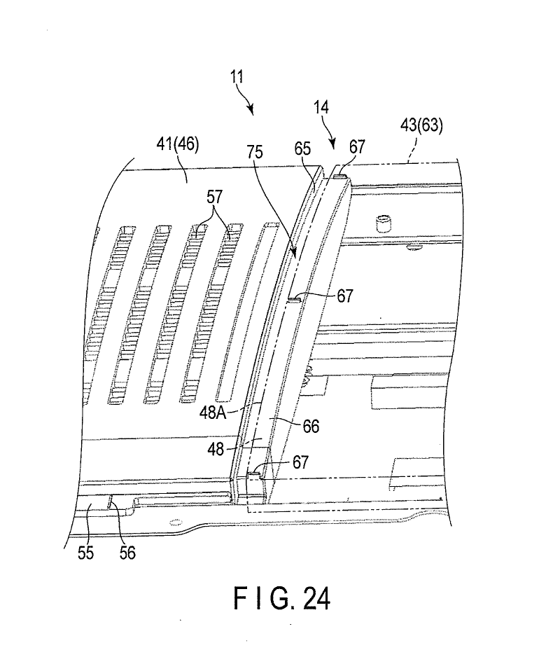

Next, a description will be given of a third embodiment of the electronic apparatus, with reference to FIG. 24. An image display device 11, which is an example of the electronic apparatus of the third embodiment, differs from that of the first embodiment in that a step 65 and overlapped margin 66 are provided in each first cover 41 and in that overlapping portions 48 are provided in the third cover 43. However, other parts are the same as those of the first embodiment. In addition, a gap 75 is provided between the step 65 of each first cover 41 and the overlapping portion 48 of the third cover 43. The conditions of the gap 75, comprising a dimension thereof, are the same as those of the first embodiment.

The third embodiment successfully produces the same advantageous effect as the first embodiment does, even when the step 65 and the overlapped margin 66 are provided in each first cover 41 and the overlapping portions 48 are provided in the third cover 43.

The image display device 11 (as an electronic apparatus) is not limited only to the above embodiments, and the image display device 11 may be embodied, by modifying the components in the implementation phase without departing from its spirit. Furthermore, various inventions may be made by combining the plurality of components disclosed in the above embodiments as appropriate. For example, some of all the components described in the embodiments may be removed. Alternatively, the respective components in the different embodiments may be combined as appropriate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An image display device comprising:
a display panel;
a first attaching portion extending on a back surface of the display panel in a longitudinal direction of the display panel and provided with a first aperture; and
a first cover attached to the first attaching portion and configured to partially cover the back surface of the display panel;
the first cover comprising:
a first main body extending in a direction intersecting the longitudinal direction outside the first attaching portion;
a first extending portion extending from the first main body in the longitudinal direction; and
a first projection protruding from the first extending portion and configured to fit into the first aperture.

2. The image display device of claim 1, further comprising:
a second attaching portion extending in the longitudinal direction on the back surface of the display panel while being separated from the first attaching portion and provided with a second aperture,
wherein the first cover comprises: a second extending portion extending from the first main body in the longitudinal direction; and a second projection protruding from the second extending portion and configured to fit into the second aperture.

3. The image display device of claim 2, further comprising:
a circuit board configured to be arranged in a region between the first attaching portion and the second attaching portion on the back surface of the display panel; and
a second cover made of metal and configured to cover the region.

4. The image display device of claim 3, wherein
the first cover is made of resin, and each of the first extending portion and the second extending portion is provided outside the region.

5. The image display device of claim 4, further comprising:
a third cover made of resin, adjacent to the first extending portion and extending in the longitudinal direction outside the region,
wherein a gap is provided between the first extending portion and the third cover.

6. The image display device of claim 5, wherein
one of the first extending portion and the third cover comprises a step and an overlapped margin protruding from the step, and
the other of the first extending portion and the third cover comprises an overlapping portion configured to overlap the overlapped margin, and
the gap is provided between the step and the overlapping portion.

7. The image display device of claim 6, wherein
The overlapped margin comprises a plurality of rails configured to protrude and to abut against the overlapping portion.

8. The image display device of claim 7, wherein
the first cover comprises a plurality of chips configured to abut against the second cover.

9. The image display device of claim 8, wherein
the third cover comprises a plurality of chips configured to abut against the second cover.

10. The image display device of claim 9, further comprising:
a first fastener configured to attach the first cover to the display panel,
wherein the first main body comprises a first through-hole being longer in a direction intersecting the longitudinal direction, the first through-hole configured to allow the first fastener passing through.

11. The image display device of claim 10, further comprising:
a third fastener configured to attach the third cover to the display panel,
wherein the third cover comprises a third through-hole being longer in the longitudinal direction, the third through-hole configured to allow the third fastener passing through.

12. The image display device of claim 11, further comprising:
a third aperture in the first attaching portion,
wherein the third cover comprises: a third main body; and a projection protruding from the third main body and configured to fit into the third aperture,
a length of the third aperture in the longitudinal direction is larger than that of the projection in the longitudinal direction, and
the projection is configured to move in the third aperture, before or after thermal expansion of the third covers.

13. An image display device comprising:
a display panel with an attaching portion;
a first cover made of resin, attached to the attaching portion, and configured to cover a circumference of a back surface of the display panel;
a second cover made of metal, attached to the attaching portion, and configured to cover a center of the back surface of the display panel; and
a circuit board in the center of the back surface of the display panel.

14. An image display device comprising:
a display panel with an attaching portion;
a first cover made of resin, attached to the attaching portion, and configured to cover a back surface of the display panel;
a second cover made of metal, and attached to the first cover; and
a third cover, made of resin, attached to the attaching portion, and configured to cover the back surface of the display panel,
wherein one of the first cover and the third cover comprises a step and an overlapped margin extending from the step,
the other of the first cover and the third cover comprises an overlapping portion configured to overlap the overlapped margin, and
the step and the overlapping portion provide a gap therebetween.
